(19) United States
(12) Patent Application Publication
(10) Pub. No.: US 2009/0267679 A1
(43) Pub. Date: Oct. 29, 2009

(54) Analog multiplexer and its select signal generating method

(75) Inventor: Kunihiko Azuma, Kanagawa (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 12/382,672

(22) Filed: Mar. 20, 2009

(30) Foreign Application Priority Data
Apr. 25, 2008 (JP) 2008-115153

(51) Int. Cl. H03K 17/00

(52) U.S. Cl. 327/408; 327/407

(57) ABSTRACT

To provide an analog multiplexer capable of extending the frequency characteristic of the analog multiplexer in terms of frequency band. The analog multiplexer 1 includes a plurality of input terminals I1 to In, a reference voltage input terminal REF, a first output terminal O1, a second output terminal O2, a plurality of switches M1x to Mnx each of which is connected between a respective one of the plurality of input terminals I1 to In and the first output terminal O1 and configured to establish a conductive state between the respective one of the input terminals and the first output terminal I1 to In based on a control signal, a plurality of dummy switches MD1x to MDnx that are connected between the input terminal I1 to In and the second output terminal O2 and set to a non-conductive state, a dummy switch MD1y that is connected between the reference voltage input terminal REF and the first output terminal O1 and set to a non-conductive state, a switch M1y that is connected between the reference voltage input terminal REF and the second output terminal O2 and set to a conductive state, and a buffer amplifier A1 that outputs a differential potential between the first output terminal O1 and the second output terminal O2.

### BACKGROUND

1. Field of the Invention

The present invention relates to a multiplexer that selects and outputs one of a plurality of input signals in accordance with a control signal. In particular, the present invention relates to an analog multiplexer that selects one of analog input signals in a wide band.

2. Description of Related Art

A television set has several analog video input terminals and a function to make a selection from received analog video input signals such as an output from a tuner, an output from a DVD player, and an output from a personal computer (PC) so that it can select one of the several input signals and display images from the selected signal. An analog multiplexer is used to realize such a switching function.

Such an analog multiplexer for video signals is required to have a frequency characteristic from the input to the output that covers a sufficiently wide frequency band for the analog video input signal frequency band. In addition, it is also necessary to have a minimum signal leak (crosstalk) from the input to the output of the non-selected video input terminals.

FIG. 11 shows a circuit diagram of an analog multiplexer 9 in the related art. As shown in FIG. 11, the analog multiplexer 9 includes a switch portion AMUX9 to perform switching between input signals, and a buffer amplifier A9 to amplify and output the output from the switch portion AMUX9.

The switch portion AMUX9 includes: 1st to nth (n=2, 3, 4, . . . ) input terminals I1 to In each of which receives a corresponding one of n input signals, i.e., 1st to nth input signals E1 to En; an output terminal O9 which outputs an selected input signal; 1ath to nath switches M1a to Mna, lbth to nbth switches M1b to Mnb, and lcth to ncth switches M1c to Mnc all of which connect between the 1st to nth input terminal I1 to In and the output terminal O9; and a decoder DEC9 which controls On/Off of the switches in accordance with a control signal SEL received from a control input terminal IS. The buffer amplifier A9 receives an output signal Eo from the output terminal O9 of the switch portion AMUX9, amplifies the received signal to a level sufficient to drive a load connected to the buffer amplifier output terminal OUT, and outputs the amplified signal.

In the switch portion AMUX9, the 1ath to nath switches M1a to Mna, the 1bth to nbth switches M1b to Mnb, and the 1cth to ncth switches M1c to Mnc are N-channel MOS transistors. The drain electrodes of the 1ath to nath switches M1a to Mna are connected to respective 1st to nth input terminals I1 to In, and the source electrodes of the 1bth to nbth switches M1b to Mnb are connected to the output terminal O9. The source electrodes of the 1ath to nath switches M1a to Mna are connected in common with the drain electrodes of the respective 1bth to nbth switches M1b to Mnb, and they are also connected to the drain electrodes of the respective lcth to ncth switches M1c to Mnc. All of the source electrodes of the 1cth to ncth switches M1c to Mnc are connected to ground.

The gate electrodes of the 1ath to nath switches M1a to Mna, the 1bth to nbth switches M1b to Mnb, and the 1cth to ncth switches M1c to Mnc are connected to 1ath to the nath decode output S1a to Sna, 1bth to the nbth decode output S1b to Snb, 1cth to the ncth decode output S1c to Snc, respectively, of the decoder DEC 9.

When the kth (1≦k≦n) input signal Ek is to be selected, the switch portion AMUX9 is controlled such that the Kath switch Mka and Kbth switch Mkb are turned on at the same time, and the Kcth switch Mkc is turned off also at the same time. The Kath switch Mka and the Kbth switch Mkb are located between the kth input terminal Ik and the output terminal O9, and when turned on, they connect between the kth input terminal Ik and the output terminal O9.

At the same time, all of the iath (1≦i≦n; i≠k) switches Mia and the ibth switches Mib that are located between the non-selected ith input terminals and the output terminal O9 are turned off by the decoder DEC9. A capacitance as shown in FIG. 12 exists between each electrode pair of the iath switches Mia and the ibth switches Mib when they are in the Off-states. Therefore, the non-selected ith input terminals Ii are connected to the output terminal O9 through these capacitances.

FIG. 12 shows capacitances between electrodes of an N-channel MOS transistor for use in the 1ath to nath switches M1a to Mna, the 1bth to nbth switches M1b to Mnb, and the 1cth to ncth switches M1c to Mnc. A terminal G, a terminal D, a terminal S, and a terminal B represent a gate electrode, a drain electrode, a source electrode, and a substrate electrode respectively. Furthermore, the signs Cgd, Cgs, Cgb, Cdb, and Csb represent a capacitance between the gate and the drain, a capacitance between the gate and the source, a capacitance between the gate and the substrate, a capacitance between the drain and the substrate, and a capacitance between the source and the substrate respectively. Since the non-selected ith input terminals Ii are connected to the output terminal O9 through the capacitance between the source and the drain of the iath switch Mia, and the capacitance between the source and the drain of the ibth switch Mib, crosstalk from the non-selected ith input terminals Ii to the output terminal O9 is caused through these capacitances. To reduce this crosstalk, the icth switches Mic that are connected between the common connection points of the source electrodes of the iath switches Mia and the drain electrodes of the ibth switches Mib and the ground are turned on, so that the signal paths from the non-selected ith input terminals Ii to the output terminal O9 are connected to the ground through the low resistance midway through the paths.

Next, the frequency characteristic of the analog multiplexer 9 is explained hereinafter. In the switch portion AMUX9, N-channel MOS transistors are used for the 1ath to nath switches M1a to Mna, the 1bth to nbth switches M1b to Mnb, and the 1cth to ncth switches M1c to Mnc. In an N-channel transistor, the structure on the source electrode side viewed from the center of the gate electrode is symmetric to the structure on the drain electrode side also viewed from the center of the gate electrode. Therefore, among all of the capacitances between the electrode pairs, the gate-drain capacitance Cgd is equal to the gate-source capacitance Cgs, and the drain-substrate capacitance Cdb is equal to the source-substrate capacitance Csb. Therefore, an equivalent circuit of each of the 1ath to nath switches M1a to Mna, the 1bth to nbth switches M1b to Mnb, and the 1cth to ncth switches M1c to Mnc can be drawn as shown in FIG. 13 when it is turned on, and can be drawn as shown in FIG. 14 when it is turned off.

FIG. 13 shows an equivalent circuit when the switch is turned on. A resistance R between the terminals D and S represents the On-resistance between the drain and the source of the N-channel MOS transistor when it is in the On-state. A first capacitance C1 and a second capacitance C2 can be expressed by the following equations (1) and (2) containing the source-substrate capacitance Csb and the gate-source capacitance Cgs shown in FIG. 12. Note that when the switch is turned on, a channel that is generated between the gate and the substrate shields between the gate and the substrate, and therefore the gate-substrate capacitance Cgb does not exist. Consequently, the first capacitance C1 and the second capacitance C2 do not contain the term of the gate-substrate capacitance Cqb.

$$\begin{matrix}{C}_{1} = {C}_{sb} & ( 1 ) \\ {C}_{2} = \frac{1}{2} {C}_{gs} & ( 2 )\end{matrix}$$

FIG. 14 shows an equivalent circuit when the switch is turned off. A third capacitance C3 and a fourth capacitance C4 can be expressed by the following equations (3) and (4) containing the source-substrate capacitance Csb and the gate-substrate capacitance Cgb shown in FIG. 12.

$$\begin{matrix}{C}_{3} = \frac{{C}_{gs} \cdot {C}_{gb}}{2 {C}_{gs} + {C}_{gb}} + {C}_{sb} & ( 3 ) \\ {C}_{4} = \frac{{C}_{gs}^{2}}{2 {C}_{gs} + {C}_{gb}} & ( 4 )\end{matrix}$$

In the analog multiplexer 9 shown in FIG. 11, the switches in the On-states and the switches in the Off-states can be replaced by the equivalent circuits shown in FIGS. 13 and 14 respectively. Therefore, when the kth input signal Ek received at the kth input terminal Ik is selected and output, the output signal Eo can be expressed by the following equation (5).

$${E}_{o} = \frac{{H}_{1 , n - 1} \cdot {H}_{3}}{1 - {H}_{1 , n - 1} \cdot {H}_{3} - ( n - 1 ) \cdot {H}_{2 , n - 1} \cdot {H}_{4}} \cdot {E}_{k} + \frac{{H}_{2 , n - 1} \cdot {H}_{4}}{1 - {H}_{1 , n - 1} \cdot {H}_{3} - ( n - 1 ) \cdot {H}_{2 , n - 1} \cdot {H}_{4}} \cdot {\sum }_{{i = 1}_{i \neq k}}^{n} {E}_{i} \qquad ( 5 )$$

In the equation (5), the first term on the right side represents the component of the selected kth input signal Ek contained in the output signal Eo. The coefficient multiplied to the kth input signal Ek indicates a frequency characteristic from the kth input terminal IK to the output terminal O9 and to the buffer amplifier output terminal OUT. Meanwhile, the second term on the right side represents the component derived from the non-selected ith input signals Ei input to the ith input terminals that is also contained in the output signal Eo. That is, it indicates the crosstalk components. The coefficient multiplied to the ith input signals Ei (i≠k) indicates the frequency characteristic of the crosstalk components. Note that coefficients contained on the right side of the equation (5) are expressed by the following equations (6), (7), (8), and (9) respectively.

$$\begin{matrix}{H}_{1 , n - 1} = \frac{1 + j \cdot ( ω / {ω}_{α} ) \cdot α}{1 + j \cdot ( ω / {ω}_{α} ) \cdot \{ 1 + ( n - 1 ) \cdot ( {ω}_{α} / {ω}_{β} ) \}} & ( 6 ) \\ {H}_{2 , n - 1} = \frac{j \cdot ( ω / {ω}_{α} ) \cdot ( {ω}_{α} / {ω}_{β} ) \cdot β}{1 + j \cdot ( ω / {ω}_{α} ) \cdot \{ 1 + ( n - 1 ) \cdot ( {ω}_{α} / {ω}_{β} ) \}} & ( 7 ) \\ {H}_{3} = \frac{1 + j \cdot ( ω / {ω}_{α} ) \cdot α}{2 + j \cdot ( ω / {ω}_{α} ) \cdot \{ 2 + ( {ω}_{α} / {ω}_{β} ) \}} & ( 8 ) \\ {H}_{4} = \frac{j \cdot ( ω / {ω}_{α} ) \cdot ( {ω}_{α} / {ω}_{β} ) \cdot β}{1 + j \cdot ( ω / {ω}_{α} ) \cdot \{ 1 + 2 \cdot ( {ω}_{α} / {ω}_{β} ) \}} & ( 9 )\end{matrix}$$

The sign ω in the equations (6), (7), (8), and (9) is an angular frequency, and the other constants are expressed by the following equations by using the resistance R, the first capacitance C1, the second capacitance C2, the third capacitance C3, and the fourth capacitance C4 shown in FIGS. 13 and 14.

$$\begin{matrix}{ω}_{α} = {C}_{α} \cdot R & ( 10 ) \\ {ω}_{β} = {C}_{β} \cdot R & ( 11 ) \\ {C}_{α} = {C}_{1} + {C}_{2} & ( 12 ) \\ α = \frac{{C}_{2}}{{C}_{1} + {C}_{2}} & ( 13 ) \\ {C}_{β} = {C}_{3} + {C}_{4} & ( 14 ) \\ β = \frac{{C}_{4}}{{C}_{3} + {C}_{4}} & ( 15 )\end{matrix}$$

A frequency characteristic of the analog multiplexer 9 and a frequency characteristic of the crosstalk component in the related art obtained by numerical calculation using the equation (5) in the case of input number n=2 are shown in FIGS. 15 and 16 respectively. Numerical values used as the parameters in the numerical calculation were extracted from electrical characteristics between terminals of an N-channel MOS transistor and shown below.

(ω_{α}/ω_{β})=0.54

α=0.49

β=0.08

n=2

FIG. 15 shows a frequency characteristic of the analog multiplexer 9 in the case of input number n=2. FIG. 15, in which an angular frequency (ω/ωα) based on ωα is used as the variable, shows a low-pass characteristic in which the voltage gain decreases with increase in the angular frequency. FIG. 16 shows a frequency characteristic of the crosstalk of the analog multiplexer 9 in the case of input number n=2. FIG. 16, in which an angular frequency (ω/ωα) based on ωα is used as the variable, shows a high-pass characteristic in which the crosstalk level increases with increase in the angular frequency.

Next, FIG. 17 shows a change in the frequency characteristic in the analog multiplexer 9 as the number of inputs “n” is increased. FIG. 17, in which the number of inputs “n” is used as the variable, shows a change in the angular frequency at which the pass gain is lowered by 3 dB (hereinafter simply called “cutoff angular frequency”) in the low-pass characteristic exhibited by the analog multiplexer 9. In the graph, the angular frequency is expressed as an angular frequency (ω/ωα) based on ωα. The cutoff angular frequency decreases with increase in the number of inputs “n”.

For example, Japanese Unexamined Patent Application Publication No. 8-293775 (Patent document 1) discloses an analog switch capable of minimizing a crosstalk amount from an input analog signal on the non-selected side to an output signal on the selected side and thus outputting an analog signal with high accuracy. In the analog switch disclosed in Patent document 1, two switches are arranged in series between the input and the output.

In the analog multiplexer 9 in the related art, On-resistances of two switches are connected in series between the selected input terminal Ik and the output terminal O9. Furthermore, the source electrodes of the same number of switches as the number of input terminals are connected in common with the output terminal O9 (i.e., all source electrodes of the same number of switches as the number of input terminals are connected to the output terminal O9). Therefore, the analog multiplexer 9 becomes a low-pass circuit that is composed of the source-substrate capacitances of all switches connected to the On-resistances of two switches and the output terminal O9. Furthermore, in the analog multiplexer, the source-substrate capacitances of all switches connected to the output terminal increases with increase in the number of input terminals. As a result, the cutoff frequency of the low-pass circuit is lowered.

### SUMMARY

As has been described above, the present inventors have found a problem that it is difficult to extend the frequency characteristic of an analog multiplexer in terms of frequency band.

A first exemplary aspect of an embodiment of the present invention is an analog multiplexer including: a plurality of input terminals; at least one reference voltage input terminal; a first output terminal; a second output terminal; a first switch portion including a plurality of switches, the plurality of switches being connected between the respective input terminals and the first output terminal and configured to establish a conductive state between one of the plurality of input terminals and the first output terminal based on a control signal; a second switch portion including a plurality of switches, the plurality of switches being connected between the respective input terminals and the second output terminal and set to a non-conductive state; a third switch potion including at least one switch, the at least one switch being connected between the reference voltage input terminal and the first output terminal and set to a non-conductive state; a fourth switch potion including at least one switch, the at least one switch being connected between the reference voltage input terminal and the second output terminal and set to a conductive state; and an output portion that outputs a differential potential between the first output terminal and a second output terminal.

In an analog multiplexer having a configuration like that, since there is only one switch between the input and the output, it is possible to raise the cutoff frequency of the low-pass circuit in comparison to the analog multiplexer circuit in which plural switches are arranged between the input and the output. Furthermore, the first output terminal can output a first output signal containing an input signal from a selected input terminal and a crosstalk signal, and the second output terminal can output a second output signal containing the same crosstalk component as the crosstalk component contained in the first output signal. By outputting a difference between the first output signal and the second output signal by the output portion, the analog multiplexer can output a signal from which the crosstalk component is removed. In this way, it is possible to extend the frequency characteristic of the analog multiplexer in terms of frequency band.

Another exemplary aspect of an embodiment of the present invention is an analog multiplexer including: a plurality of input terminals; at least one reference voltage input terminal; a first output terminal; a second output terminal; a first switch circuit potion including switches each of which is connected between a respective one of the plurality of input terminals and the first output terminal, the first switch circuit potion being configured to generate a first output signal containing an input signal selected by the switches based on a control signal and a crosstalk component caused between the plurality of input terminals and the first output terminal and between the at least one reference voltage input terminal and the first output terminal, and output the generated first output signal to the first output terminal; a second switch circuit portion that generates a second output signal containing the same component as the crosstalk component contained in the first output signal by using a crosstalk component caused between the plurality of input terminal and the second output terminal and between the at least one reference voltage input terminal and the second output terminal, and outputs the generated second output signal to the second output terminal; and an output portion that outputs a differential potential between the first output terminal and the second output terminal.

Another exemplary aspect of an embodiment of the present invention is a method of generating a select signal of an analog multiplexer, the analog multiplexer including a plurality of input terminals, at least one reference voltage input terminal, a first output terminal, and a second output terminal, the method including: selecting an input signal by switches based on a control signal, each of the switches being connected between a respective one of the plurality of input terminals and the output terminal; generating a first output signal containing the selected input signal and a crosstalk component caused between the plurality of input terminals and the first output terminal and between the at least one reference voltage input terminal and the first output terminal, and outputting the generated first output signal to the first output terminal; generating a second output signal containing the same component as the crosstalk component contained in the first output signal by using a crosstalk component caused between the plurality of input terminals and the second output terminal and between the at least one reference voltage input terminal and the second output terminal, and outputting the generated second output signal to the second output terminal; and outputting a differential potential between the first output terminal and the second output terminal.

The present invention enables to extend the frequency characteristic of an analog multiplexer in terms of frequency band.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a circuit diagram of an analog multiplexer in accordance with an exemplary embodiment of the present invention;

FIG. 2 is a graph showing an input-output frequency characteristic of the analog multiplexer shown in FIG. 1 in accordance with an exemplary embodiment;

FIG. 3 is a graph showing the relation between the number of inputs and cutoff frequencies of the analog multiplexer shown in FIG. 1 in accordance with an exemplary embodiment;

FIG. 4 is a graph showing an input-output frequency characteristic of the analog multiplexer shown in FIG. 1 in accordance with another exemplary embodiment;

FIG. 5 is a graph showing the relation between the number of inputs and cutoff frequencies of the analog multiplexer shown in FIG. 1 in accordance with another exemplary embodiment;

FIG. 6 is a circuit diagram of an analog multiplexer in accordance with another exemplary embodiment of the present invention;

FIG. 7 is a graph showing an input-output frequency characteristic of the analog multiplexer shown in FIG. 6;

FIG. 8 is a graph showing the relation between the number of inputs and cutoff frequencies of the analog multiplexer shown in FIG. 6;

FIG. 9 is a circuit diagram of an analog multiplexer in accordance with another exemplary embodiment of the present invention;

FIG. 10 is a graph showing an input-output frequency characteristic of the analog multiplexer shown in FIG. 9;

FIG. 11 is a circuit diagram of an analog multiplexer in the related art;

FIG. 12 is a circuit diagram illustrating a capacitance between the terminals of an N-channel MOS transistor shown in FIG. 11;

FIG. 13 is a circuit diagram illustrating an equivalent circuit of an N-channel MOS transistor shown in FIG. 11 while it is in the On-state;

FIG. 14 is a circuit diagram illustrating an equivalent circuit of an N-channel MOS transistor shown in FIG. 11 while it is in the Off-state;

FIG. 15 is a graph showing an input-output frequency characteristic of the analog multiplexer shown in FIG. 11;

FIG. 16 is a graph showing a frequency characteristic of crosstalk in the analog multiplexer shown in FIG. 11; and

FIG. 17 is a graph showing the relation between the number of inputs and cutoff frequencies of the analog multiplexer shown in FIG. 11.

### DETAILED DESCRIPTION OF THE EXEMPLARY EMBODIMENTS

Exemplary embodiments of the present invention are explained hereinafter with reference to the drawings. To clarify the explanation, omissions and simplifications are made as appropriate in the following description and the drawings. The same signs are assigned to components and equivalent portions having identical structures or functions throughout the drawings, and explanation of them are omitted as appropriate.

An analog multiplexer in accordance with an exemplary embodiment of the present invention includes a plurality of input terminals and two output terminals (first and second output terminals), and only one switch that is used to switch the input is connected between each of the input terminals and the first output terminal. Furthermore, dummy switch circuits connected between the respective input terminals and the second output terminal, between the first output terminal and the reference voltage input terminal, and between the second output terminal and the reference voltage input terminal, respectively, are provided so that a differential voltage between the first output terminal and the second output terminal is output.

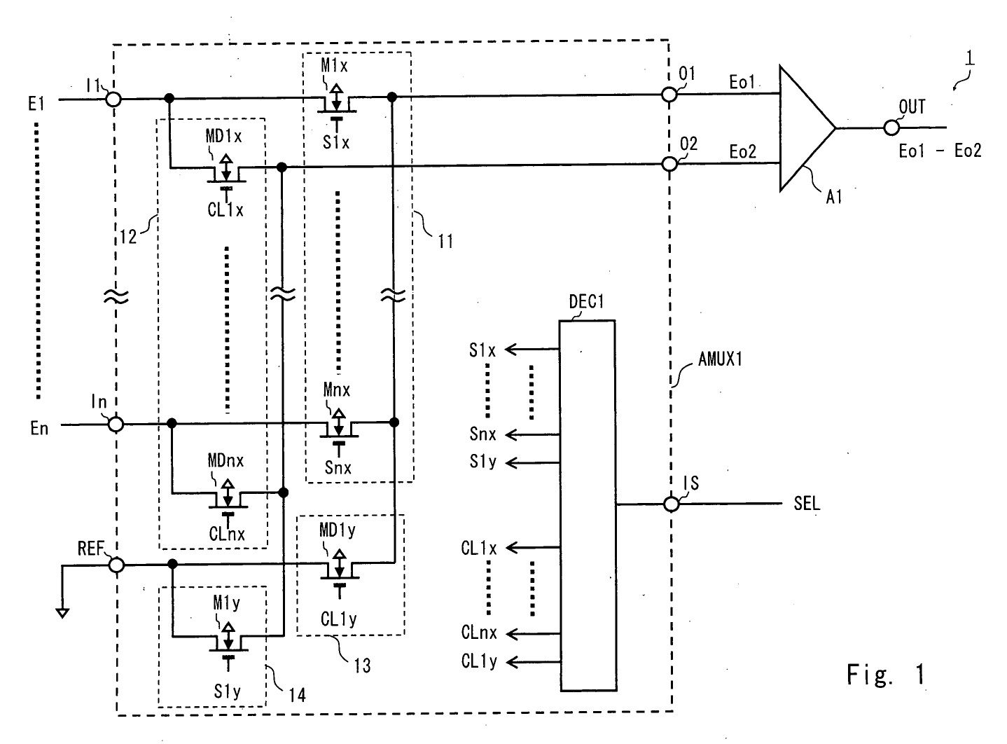

The details of an analog multiplexer in accordance with an exemplary aspect of the present invention are explained hereinafter with reference to the structure of an analog multiplexer 1 in accordance with an exemplary embodiment shown in FIG. 1. An analog multiplexer in accordance with an exemplary aspect of the present invention includes a plurality of input terminals I1 to In (n≧2), at least one reference voltage input terminal REF, a first output terminal O1, and a second output terminal O2. The analog multiplexer further includes first to fourth switch portions 11 to 14 and an output portion (buffer amplifier A1) The first switch portion 11 includes a plurality of switches that are connected between the respective input terminals I1 to In and the first output terminal O1 and configured to establish a conductive state between one of the plurality of input terminals I1 to In and the first output terminal based on a control signal. The second switch portion 12 includes a plurality of switches that are connected between the respective input terminals I1 to In and the second output terminal O2 and set to a non-conductive state. The third switch potion 13 includes at least one switch that is connected between the at least one reference voltage input terminal REF and the first output terminal O1 and set to a non-conductive state. The fourth switch potion 14 includes at least one switch that is connected between the at least one reference voltage input terminal REF and the second output terminal O2 and set to a conductive state.

With the structure of the first to fourth switch portions 11 to 14 like this, the first output terminal O1 outputs a first output signal Eo1 containing an input signal selected from input signals at the plurality of input terminals I1 to In and a crosstalk component from the plurality of input terminals I1 to In to the first output terminal O1. The second output terminal O2 outputs a second output signal Eo2 containing the same component as the crosstalk component in the first output signal Eo1. Furthermore, the output portion outputs a differential potential between the first output terminal O1 and the second output terminal O2. With a structure like this, the frequency characteristic from the input to the output of the analog multiplexer is extended in terms of frequency band. Specific exemplary embodiments are explained hereinafter.

### First Exemplary Embodiment

FIG. 1 is a circuit diagram of an analog multiplexer in accordance with an exemplary embodiment of the present invention. An analog multiplexer 1 in accordance with an exemplary embodiment of the present invention includes a switch portion AMUX1 that performs switching between input signals, and a buffer amplifier A1 (output portion) that receives an output from the switch portion AMUX1, and amplifies and outputs the received output.

The switch portion AMUX1 includes: 1st to nth (n=2, 3, 4, . . . ) input terminals I1 to In each of which receives a corresponding one of n input signals, i.e., 1st to nth input signals E1 to En; a reference voltage input terminal REF fixed at a ground potential; a first output terminal O1; a second output terminal O2; 1xth to nxth switches M1x to Mnx connected between the input terminals I1 to In and the first output terminal O1; 1xth to nxth dummy switches MD1x to MDnx connected between the input terminals I1 to In and the second output terminal O2; 1yth dummy switch MD1y connected between the reference voltage input terminal REF and the first output terminal O1; 1yth switch M1y connected between the reference voltage input terminal REF and the second output terminal O2; and a decoder DEC1 that controls On/Off of the switches in accordance with a control signal SEL received from a control input terminal IS.

The buffer amplifier A1 receives a first output signal Eo1 from the first output terminal O1 of the switch portion AMUX1 and a second output signal Eo2 from the second output terminal O2, generates a differential voltage Eo1-Eo2 between an output from the first output terminal O1 and an output from the second output terminal O2, amplifies the differential voltage to a level sufficient to drive a load connected to the buffer amplifier output terminal OUT, and outputs the amplified differential voltage.

In the switch portion AMUX1, the 1xth to nxth switches M1x to Mnx, the 1xth to nxth dummy switches MD1x to MDnx, the 1yth dummy switch MD1y, and the 1yth switch M1y are N-channel MOS transistors. The drain electrodes of the 1xth to nxth switches M1x to Mnx and the drain electrodes of the respective 1xth to nxth dummy switches MD1x to MDnx are connected in common with the respective 1st to nth input terminals I1 to In. Furthermore, the drain electrode of the 1yth dummy switch MD1y and the 1yth switch M1y are connected in common with the reference voltage input terminal REF. The source electrodes of the 1xth to nxth switches M1x to Mnx and the source electrode of the 1yth dummy switch MD1y are all connected in common with the first output terminal O1. The source electrodes of the 1xth to nxth dummy switches MD1x to MDnx and the source electrode of the 1yth switch M1y are all connected in common with the second output terminal O2. The gate electrodes of the 1xth to nxth switches M1x to Mnx are connected to the respective 1xth to nxth decode outputs S1x to Snx of the decoder DEC1, and the gate electrodes of the 1xth to nxth dummy switches MD1x to MDnx are connected to the respective 1xth to nxth clamp outputs CL1x to CLnx of the decoder DEC1. The gate electrodes of the 1yth switch M1y and the 1yth dummy switch MD1y are connected to the 1yth decode output S1y and the 1yth clamp output CL1y, respectively, of the decoder DEC1.

Next, an operation of the analog multiplexer 1 in accordance with an exemplary embodiment of the present invention shown in FIG. 1 in a case where the kth (1≦k≦n) input signal Ek is selected is explained hereinafter. The non-selected input signals, input terminals, switches, and the likes are expressed by using the sign “i” (1≦i≦n; i≠k). The 1xth to nxth decode outputs S1x to Snx of the decoder DEC1 are controlled such that the kxth switch Mkx is turned on and, at the same time, all of the ixth switches Mix are turned off. The kxth switch Mkx is located between the kth input terminal Ik and the first output terminal O1, and when turned on, it connects between the kth input terminal Ik and the first output terminal O1. The ixth switches Mix are connected to the non-selected ith input terminals.

Furthermore, the 1xth to nxth dummy switches MD1x to MDnx, the 1yth dummy switch MD1y, and the 1yth switch M1y constitutes a dummy switch circuit in which the On/Off states are constantly fixed regardless of input switching. Furthermore, the 1xth to nxth dummy switches MD1x to MDnx, the 1yth dummy switch MD1y, and the 1yth switch M1y are controlled by the 1xth to nxth clamp outputs CL1x to CLnx, the 1yth clamp output CL1y, and the 1yth decode output S1y of the decoder DEC1 such that they are constantly in the Off-state, Off-state, and On-state respectively.

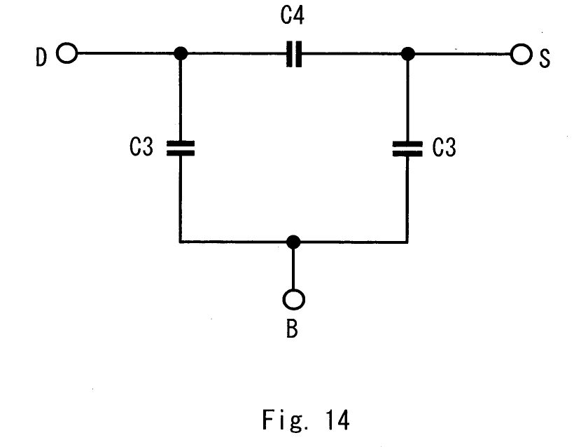

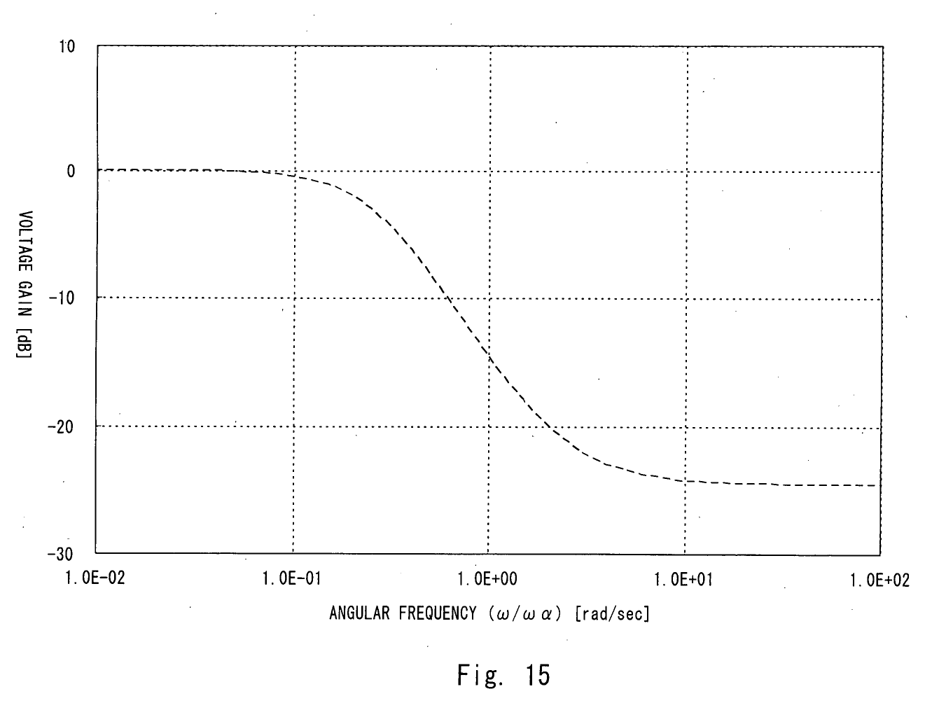

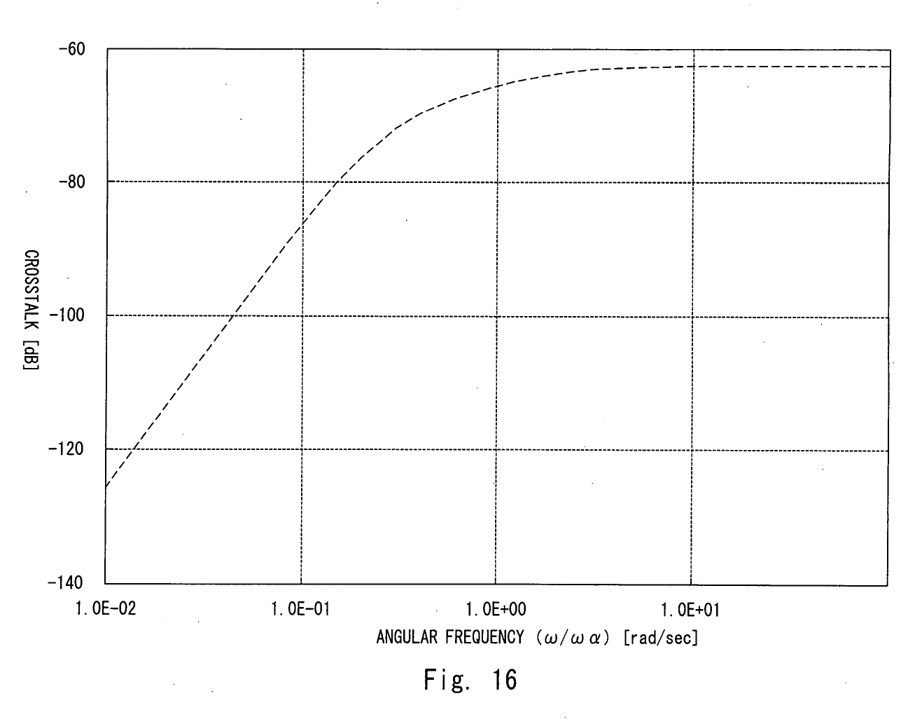

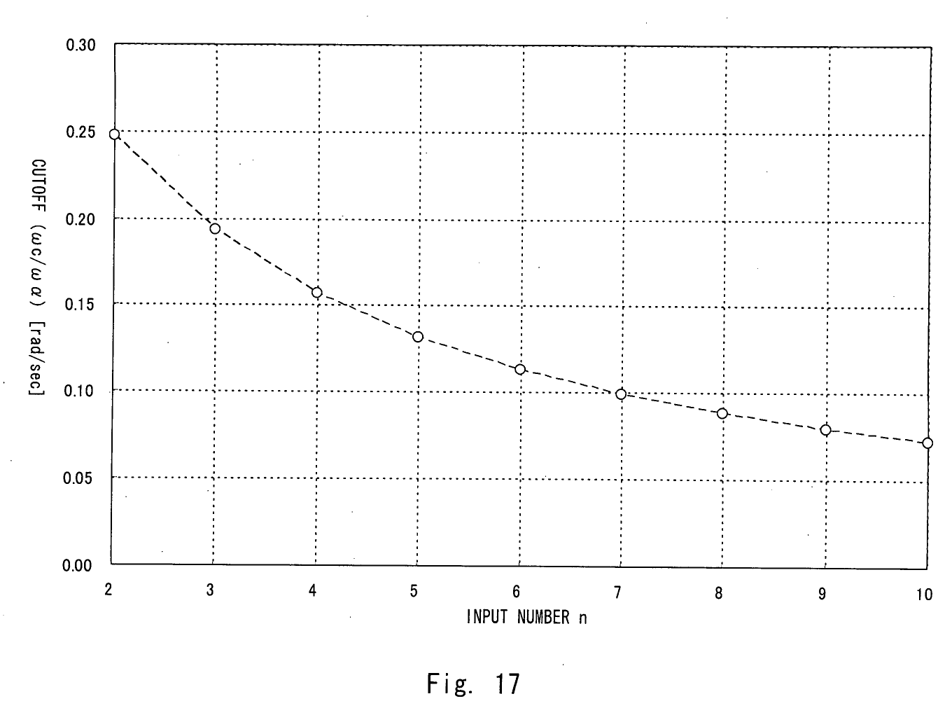

In the analog multiplexer 1 in accordance with an exemplary embodiment of the present invention shown in FIG. 1, each of the kxth switch Mkx and the 1yth switch M1y in the On-state can be replaced by an equivalent circuit shown in FIG. 13. Furthermore, each of the ixth switches Mix, the 1xth to nxth dummy switches MD1x to MDnx, and the 1yth dummy switch MD1y in the Off-state can be replaced by an equivalent circuit shown in FIG. 14. With these replacements, when the kth input signal Ek received at the kth input terminal Ik is selected and output, an output signal Eo1 from the first output terminal O1 and an output signal Eo2 from the second output terminal O2 are expressed by the following equations (16) and (17) respectively.

$$\begin{matrix}{E}_{o 1} = ( {H}_{1 , n} - {H}_{2 , n} ) \cdot {E}_{k} + {H}_{2 , n} \cdot {\sum }_{i = 1}^{n} {E}_{i} & ( 16 ) \\ {E}_{o 2} = {H}_{2 , n} \cdot {\sum }_{i = 1}^{n} {E}_{i} & ( 17 )\end{matrix}$$

In the equations, the coefficients contained on the right sides of the equations (16) and (17) are obtained by replacing “n−1” with “n” in the equations (6) and (7), and expressed by the following equations (18) and (19) respectively.

$$\begin{matrix}{H}_{1 , n} = \frac{1 + j \cdot ( ω / {ω}_{α} ) \cdot α}{1 + j \cdot ( ω / {ω}_{α} ) \cdot \{ 1 + n \cdot ( {ω}_{α} / {ω}_{β} ) \}} & ( 18 ) \\ {H}_{2 , n} = \frac{j \cdot ( ω / {ω}_{α} ) \cdot ( {ω}_{α} / {ω}_{β} ) \cdot β}{1 + j \cdot ( ω / {ω}_{α} ) \cdot \{ 1 + n \cdot ( {ω}_{α} / {ω}_{β} ) \}} & ( 19 )\end{matrix}$$

In the equation (16), the first term on the right side represents the component of the selected kth input signal Ek contained in the output signal Eo1 from the first output terminal O1. The coefficient multiplied to Ek indicates a frequency characteristic from the kth input terminal IK to the first output terminal O1. Furthermore, the second term on the right side of the equation (16) is a component that is derived from the non-selected ith input signals Ei and contained in the output signal Eo1 at the first output terminal O1, and represents the crosstalk component. The coefficient multiplied to Ei indicates the frequency characteristic of the crosstalk component. The right side of the equation (17) is identical to the second term on the right side of the equation (16), and thus identical to the crosstalk component contained in the output signal Eo1 at the first output terminal O1. As can be understood from this, the output signal Eo1-Eo2 to the buffer amplifier output terminal OUT does not contain any crosstalk component as shown in the following equation (20).

Eₒ₁−Eₒ₂=(H_{1,n}−H_{2,n})·Eₖ (2 O)

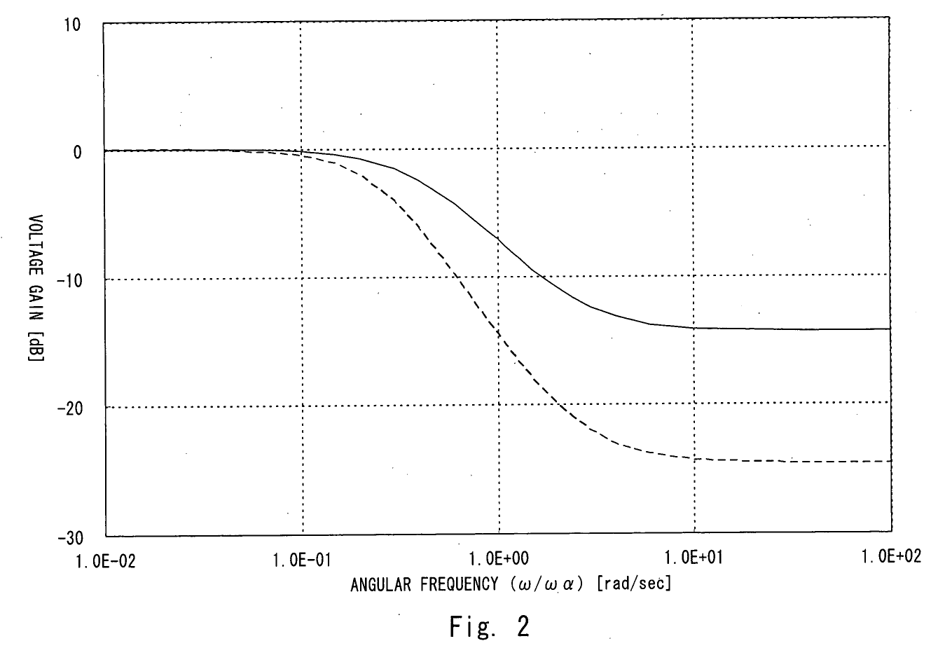

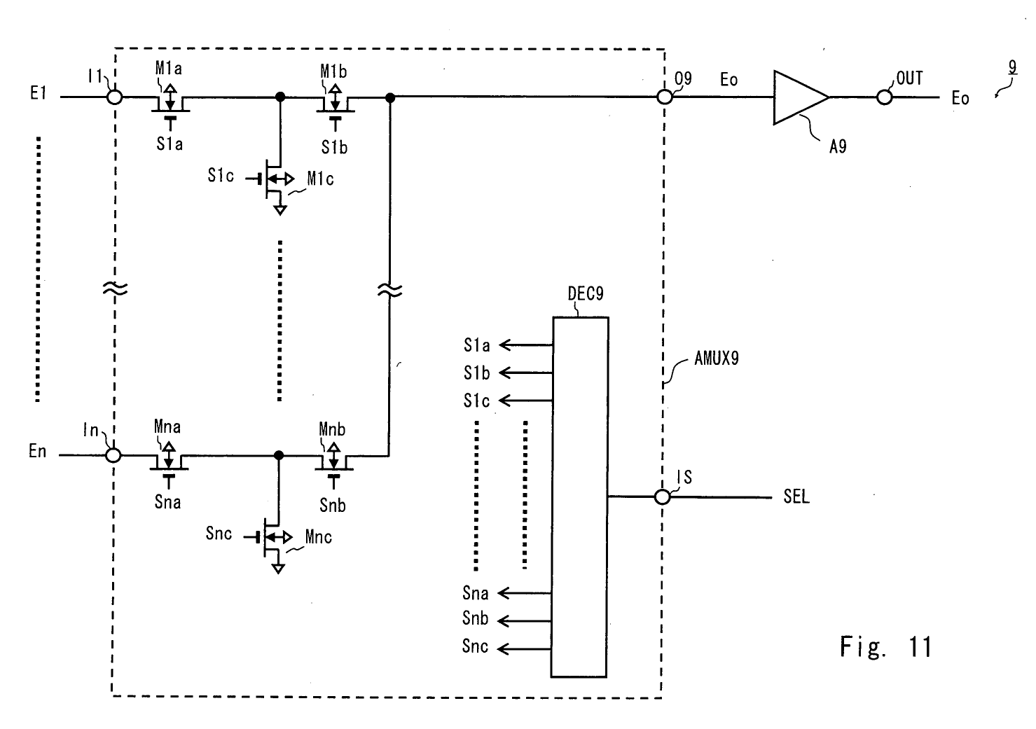

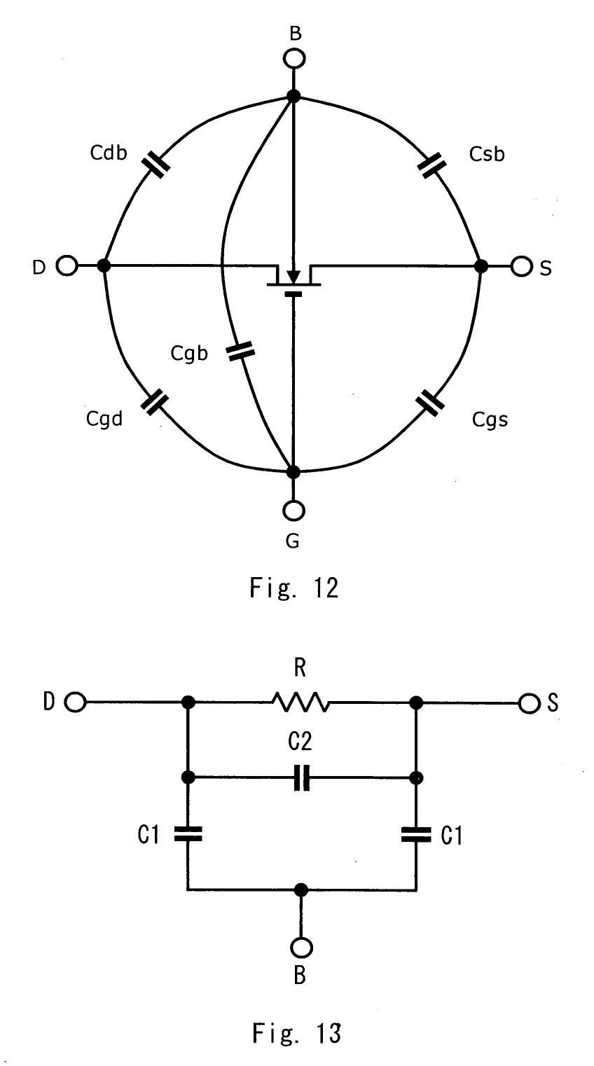

FIG. 2 shows a frequency characteristic of the analog multiplexer 1 in accordance an exemplary embodiment of the present invention obtained by numerical calculation using the equation (20) in the case of input number n=2. Furthermore, FIG. 2 also shows a frequency characteristic of the analog multiplexer 9 shown in FIG. 11 obtained by numerical calculation. Values used as the parameters in the numerical calculation are the same as those used in the numerical calculation for the frequency characteristic of the analog multiplexer 9 shown in FIG. 11, and are shown below.

(ω_{α}/ω_{β})=0.54

α=0.49

β=0.08

n=2

FIG. 2 is a graph of frequency characteristics in which an angular frequency (ω/ωα) based on ωα is used as the variable. In the graph, the solid line represents the frequency characteristic of the analog multiplexer 1 in accordance with an exemplary embodiment of the present invention, and the broken line represents the frequency characteristic of the analog multiplexer 9 shown in FIG. 11. In FIG. 2, the decrease in the voltage gain resulting from the increase in the angular frequency in the analog multiplexer 1 in accordance with an exemplary embodiment of the present invention is smaller compared to the frequency characteristic of the analog multiplexer 9 shown in FIG. 11. From this fact, it can be understood that the frequency characteristic of the analog multiplexer 1 in accordance with an exemplary embodiment of the present invention is improved over that of the analog multiplexer 9 shown in FIG. 11.

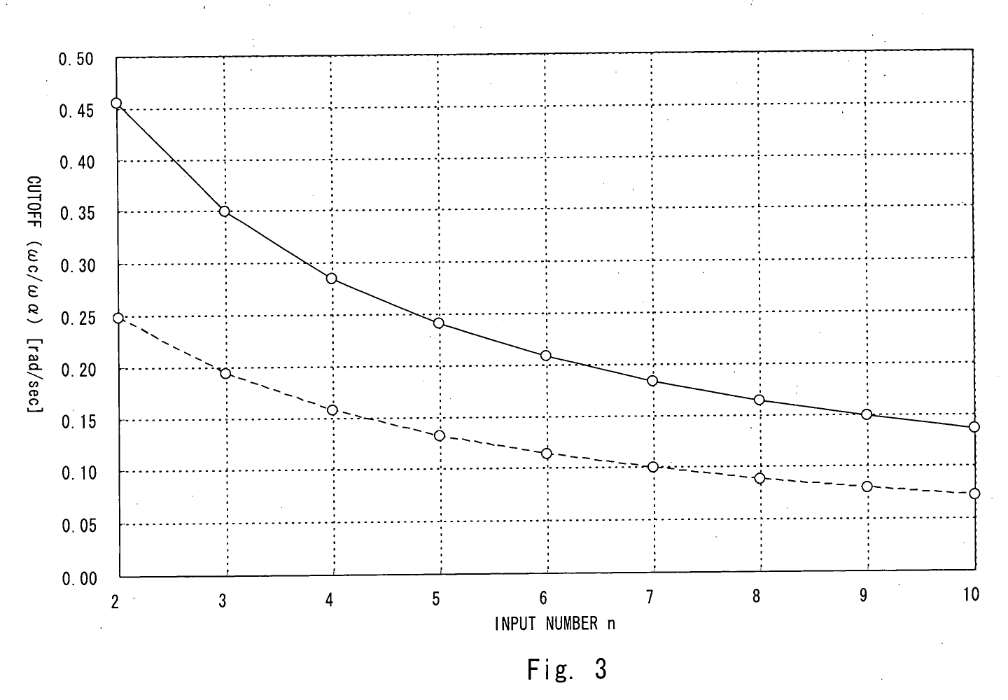

Next, FIG. 3 shows a change in the frequency characteristic in the analog multiplexer 1 in accordance with an exemplary embodiment of the present invention as the input number “n” is increased. Furthermore, FIG. 3 also shows a frequency characteristic of the analog multiplexer 9 shown in FIG. 11. FIG. 3, in which the number of inputs “n” is used as the variable, shows changes of the cutoff angular frequencies in the low-pass characteristics exhibited by the analog multiplexer 1 in accordance with an exemplary embodiment of the present invention and the analog multiplexer 9 shown in FIG. 11. In the graph, the angular frequency is expressed as an angular frequency (ω/ωα) based on ωα. The solid line represents the cutoff angular frequency of the analog multiplexer 1 in accordance with an exemplary embodiment of the present invention, and the broken line represents the cutoff angular frequency of the analog multiplexer 9 shown in FIG. 11. In the range from the point where the input number “n” is 2 to the point where the input number “n” is 10, the cutoff angular frequency of the analog multiplexer 1 in accordance with an exemplary embodiment of the present invention is about 1.8 times higher than that of the analog multiplexer 9 shown in FIG. 11. From this fact, it can be understood that the frequency characteristic of the analog multiplexer 1 in accordance with an exemplary embodiment of the present invention is extended in terms of frequency band.

As has been explained above, the switch portion AMUX1 of the analog multiplexer 1 in accordance with an exemplary embodiment of the present invention generates an output at the first output terminal O1 containing the input signal and the crosstalk component, and an output at the second output terminal O2 containing the crosstalk component alone, and removes the crosstalk component by using these two outputs. Note that the crosstalk component is a component that is caused, at the first output terminal O1, from the non-selected inputs to the output. Specifically, the switch portion AMUX1, which is provided with the dummy switch circuit and the second output terminal O2, generates the same component as the crosstalk component caused at the first output terminal O1 and outputs the generated component to the second output terminal O2. The buffer amplifier A1 can cancel out the crosstalk component by taking out a differential voltage between the output from the first output terminal O1 and the second output terminal O2.

In this way, by providing a dummy switch circuit composed of switches that are connected between the input terminal and the second output terminal, between the first output terminal and the reference voltage input terminal, and between the second output terminal and the reference voltage input terminal respectively, it is possible to make the crosstalk component caused between the input terminal and the first output terminal equal to the crosstalk component caused between the input terminal and the second output terminal. By outputting the differential voltage between the first output terminal and the second output terminal, the crosstalk component caused at the first output terminal is cancelled out by the crosstalk component caused in the second output terminal, and therefore it is possible to configure such that any crosstalk component is not contained in the output voltage.

Furthermore, since this exemplary embodiment of the present invention has such a structure that the crosstalk component is cancelled out, the switch portion AMUX1 of the analog multiplexer 1 in accordance with an exemplary embodiment of the present invention can select an input signal by using only one switch located between the input and the output. Specifically, in the switch portion AMUX9 of the analog multiplexer 9 shown in FIG. 11, two serially-connected switches are connected between the input and the output and another switch is provided between the common connection point of the two serially-connected switches and the ground. In the switch portion AMUX9, when an input is not selected, the two serially-connected switches connected between that input and the output are both turned off and the switch provided between the common connection point of the two switches and the ground is turned on so that the crosstalk component is directly connected to the ground. The analog multiplexer 1 in accordance with this exemplary embodiment of the present invention does not require such a directly-connecting function, and therefore it is possible to select an input signal by using only one switch.

Furthermore, since the analog multiplexer 1 in accordance with this exemplary embodiment of the present invention is realized by connecting one switch between a selected input and the output, the resistance caused between the selected input and the output is an On-resistance corresponding to one switch. For example, assuming that the same switches are used and the same number of input terminals are provided, the On-resistance of a switch connecting between an input terminal and the output terminal can be reduced to ½ of the On-resistance corresponding to two switches connected in series between an input and the output in the analog multiplexer 9 shown in FIG. 11. Therefore, the cutoff frequency of the low-pass circuit that is formed from the resistance between a selected input and the output and the source-substrate capacitances associated with the source electrodes of the same number of switches as the number of inputs connected to the output becomes about twice higher than that of the analog multiplexer 9 shown in FIG. 11. Therefore, it is possible to extend the frequency characteristic of the analog multiplexer in terms of frequency band.

### Second Exemplary Embodiment

Next, an analog multiplexer in accordance with another exemplary embodiment of the present invention is explained hereinafter. The analog multiplexer 2 is formed by replacing each of the N-channel MOS transistors used as the 1xth to nxth switches M1x to Mnx, the 1xth to nxth dummy switches MD1x to MDnx, the 1yth dummy switch MD1y, and the 1yth switch M1y with a P-channel MOS transistor in the analog multiplexer shown in FIG. 1. The configuration of this exemplary embodiment of the present invention is explained hereinafter also with reference to FIG. 1. Furthermore, the following explanation is made with an assumption that the analog multiplexer 1 in FIG. 1 is replaced with the analog multiplexer 2. The same signs are assigned to the same blocks as those of the analog multiplexer 1 in accordance with the previous exemplary embodiment, and explanation of them is omitted. Furthermore, the same signs as those in FIG. 1 are also assigned even to switches that are replaced by P-channel MOS transistors.

The P-channel MOS transistor has the same capacitances between the electrodes as those of the N-channel MOS transistor, i.e., a gate-drain capacitance Cgd, a gate-source capacitance Cgs, a gate-substrate capacitance Cgb, a drain-substrate capacitance Cdb, and a source-substrate capacitance Csb. Therefore, its equivalent circuit in the On-state corresponds to the equivalent circuit shown in FIG. 13, and the equivalent circuit in the Off-state corresponds to the equivalent circuit shown in FIG. 14. Similarly to the analog multiplexer 1 in accordance with the previous exemplary embodiment, the frequency characteristic from the input to the output of the analog multiplexer 2 in accordance this exemplary embodiment of the present invention is expressed by the above-mentioned equation (20). Furthermore, also similarly to the previous embodiment, its output does not contain any crosstalk component.

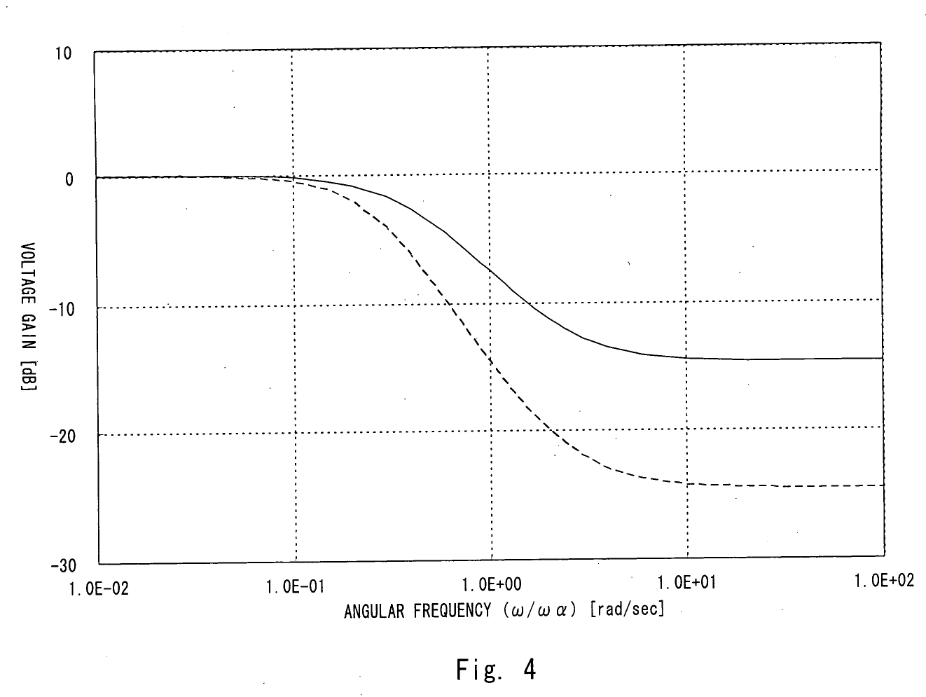

FIG. 4 shows a frequency characteristic obtained by numerical calculation using the equation (20) in the case where the input number is two. Furthermore, FIG. 4 also shows a frequency characteristic of the analog multiplexer 9 shown in FIG. 11 obtained by numerical calculation. Since the transistor switches are replaced from N-channel MOS transistors to P-channel MOS transistors, values used as the parameters in the numerical calculation were-extracted from electrical characteristics between terminals of a P-channel MOS transistor and shown below.

(ω_{α}/ω_{β})=0.69

α=0.58

β=0.20

n=2

FIG. 4 is a graph of frequency characteristics in which an angular frequency (ω/ωα) based on ωα is used as the variable. In the graph, the solid line represents the frequency characteristic of the analog multiplexer 2 in accordance with this exemplary embodiment of the present invention, and the broken line represents the frequency characteristic of the analog multiplexer 9 shown in FIG. 11. In FIG. 4, the decrease in the voltage gain resulting from the increase in the angular frequency in the analog multiplexer 2 in accordance with this exemplary embodiment of the present invention is smaller than the frequency characteristic of the analog multiplexer 9 shown in FIG. 11. From this fact, it can be understood that the frequency characteristic of the analog multiplexer 2 in accordance with this exemplary embodiment of the present invention is improved over that of the analog multiplexer 9 shown in FIG. 11.

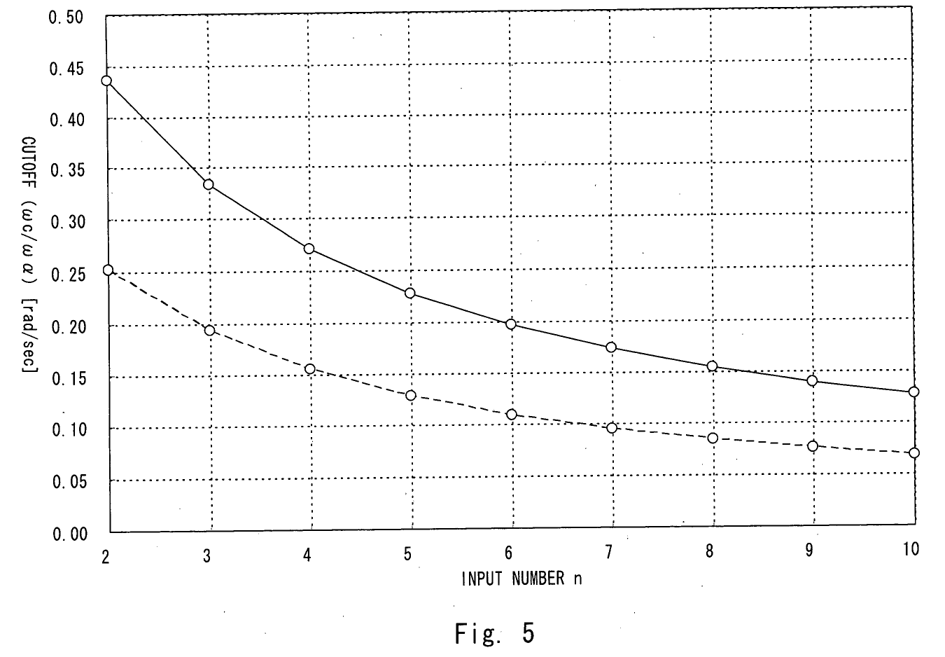

Next, FIG. 5 shows a change in the frequency characteristic in the analog multiplexer 2 in accordance with this exemplary embodiment of the present invention as the input number “n” is increased. Furthermore, FIG. 5 also shows a frequency characteristic of the analog multiplexer 9 shown in FIG. 11. FIG. 5, in which the number of inputs “n” is used as the variable, shows changes of the cutoff angular frequencies in the low-pass characteristics exhibited by the analog multiplexer 2 in accordance with this exemplary embodiment of the present invention and the analog multiplexer 9 shown in FIG. 11. In the graph, the angular frequency is expressed as an angular frequency (ω/ωα) based on ωα. The solid line represents the cutoff angular frequency of the analog multiplexer 2 in accordance with this exemplary embodiment of the present invention, and the broken line represents the cutoff angular frequency of the analog multiplexer 9 shown in FIG. 11. In the range from the point where the input number “n” is 2 to the point where the input number “n” is 10, the cutoff angular frequency of the analog multiplexer 2 in accordance with this-exemplary embodiment of the present invention is about 1.8 times higher than that of the analog multiplexer 9 shown in FIG. 11. From this fact, it can be understood that the frequency characteristic of the analog multiplexer 2 in accordance with this exemplary embodiment of the present invention is extended in terms of frequency band.

As has been described above, since P-channel MOS transistors are used in the analog multiplexer 2 in accordance with this exemplary embodiment of the present invention, their On-resistance values and the capacitance values between the electrodes are not the same as those of the N-channel MOS transistors used in the analog multiplexer 1 in accordance with the previous exemplary embodiment. However, the frequency characteristic can be still improved as in the case of the analog multiplexer 1 in accordance with the previous exemplary embodiment.

Furthermore, a switch using an N-channel transistor (including a dummy switch) is turned off if the potentials of the source electrode and the drain electrode are both brought to values close to the potential of the gate electrode. Therefore, the range of the input signal voltage is limited to the voltage lower than the gate voltage. By contrast, a switch using a P-channel transistor can be turned on/off in an input signal voltage range higher than the gate voltage. Therefore, this secondly-described exemplary embodiment can handle input signals in a voltage range that cannot be handled in the firstly-described exemplary embodiment.

Furthermore, it is also possible to form a switch portion by connecting a switch(s) composed of a P-channel MOS transistor(s) and a switch(s) composed of an N-channel MOS transistor(s) in parallel. Specifically, each of the switches and the dummy switches contained in the switch portion AMUX1 shown in FIG. 1 can be replaced by a switch formed by connecting a switch composed of a P-channel MOS transistor and a switch composed of an N-channel MOS transistor in parallel. The switches composed of P-channel MOS transistors are turned on/off in the input voltage range in which switches composed of N-channel MOS transistors are turned off, whereas the switches composed of N-channel MOS transistors are turned on/off in the input voltage range in which switches composed of P-channel MOS transistors are turned off. In this way, it is possible to extend the input voltage range in comparison to the analog multiplexer 1 of the firstly-described exemplary embodiment.

### Third Exemplary Embodiment

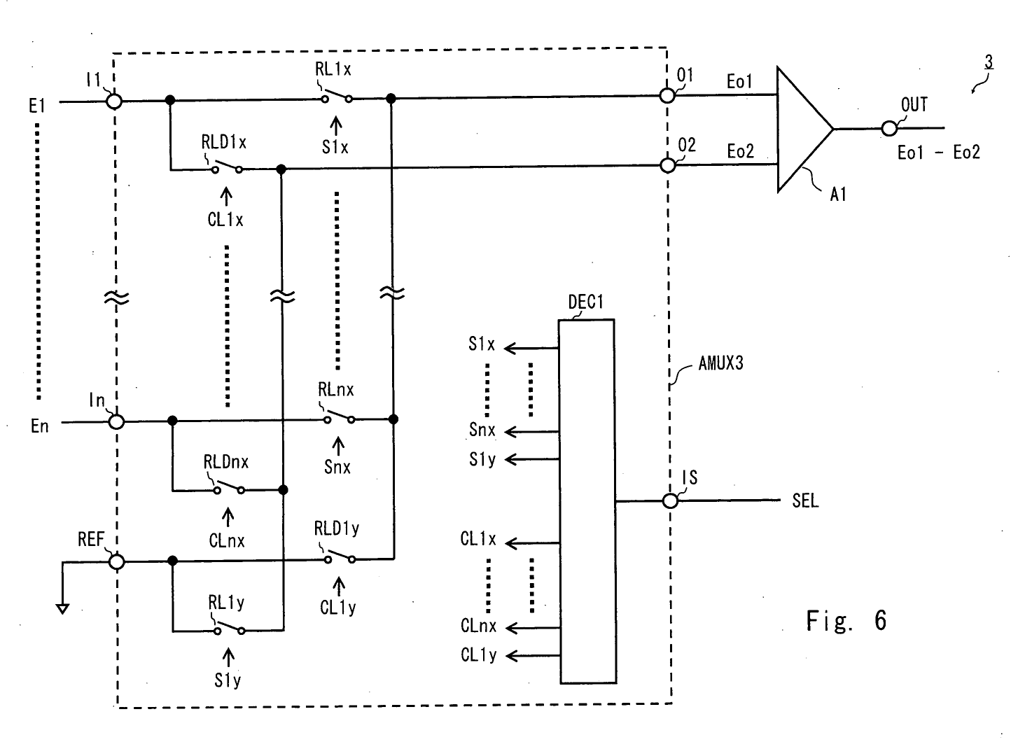

Next, an analog multiplexer in accordance with another exemplary embodiment of the present invention is explained hereinafter. FIG. 6 is a circuit diagram of an analog multiplexer in accordance with another exemplary embodiment of the present invention. The analog multiplexer 3 in accordance with this exemplary embodiment of the present invention is formed by replacing all of the N-channel MOS transistors used as the switches and the dummy switches in the analog multiplexer 1 of the firstly-described exemplary embodiment with relays. The analog multiplexer 3 shown in FIG. 6 is formed by replacing the N-channel MOS transistors used as the 1xth to nxth switches M1x to Mnx, the 1xth to nxth dummy switches MD1x to MDnx, the 1yth dummy switch MD1y, and the 1yth switch M1y with 1xth to nxth relays RL1x to RLnx, 1xth to nxth dummy relays RLD1x to RLDnx, a 1yth dummy relay RLD1y, and a 1yth relay RL1y respectively. Note that the same signs are assigned to the same blocks as those of the analog multiplexer 1 in accordance with the firstly-described exemplary embodiment, and explanation of them is omitted.

A rely that opens and closes between the connection points has capacitances between the connection points and between the connection points and the housing, and its equivalent circuit in the state where the connection points are closed is the same as the equivalent circuit shown in FIG. 13 with assumption that the first capacitance C1 is the capacitance between the connection points and the housing, the second capacitance C1 is the capacitance between the connection points, and the resistance R is the contact resistance of the connection points. Furthermore, its equivalent circuit in the state where the connection points are opened is the same as the equivalent circuit shown in FIG. 14 with assumption that the third capacitance C3 is the capacitance between the connection points and the housing, and the fourth capacitance C4 is the capacitance between the connection points. With the reasons described above, the equivalent circuits of a relay that opens and closes between the connection points are similar to those shown in FIGS. 13 and 14 that are used as the equivalent circuits of a N-channel MOS transistor.

From this fact, the frequency characteristic of the analog multiplexer 3 in accordance this exemplary embodiment of the present invention can be expressed by the above-mentioned equation (20) as in the case of the analog multiplexer 1 in accordance with the firstly-described exemplary embodiment. Furthermore, no crosstalk component is contained in the output at the buffer amplifier terminal OUT.

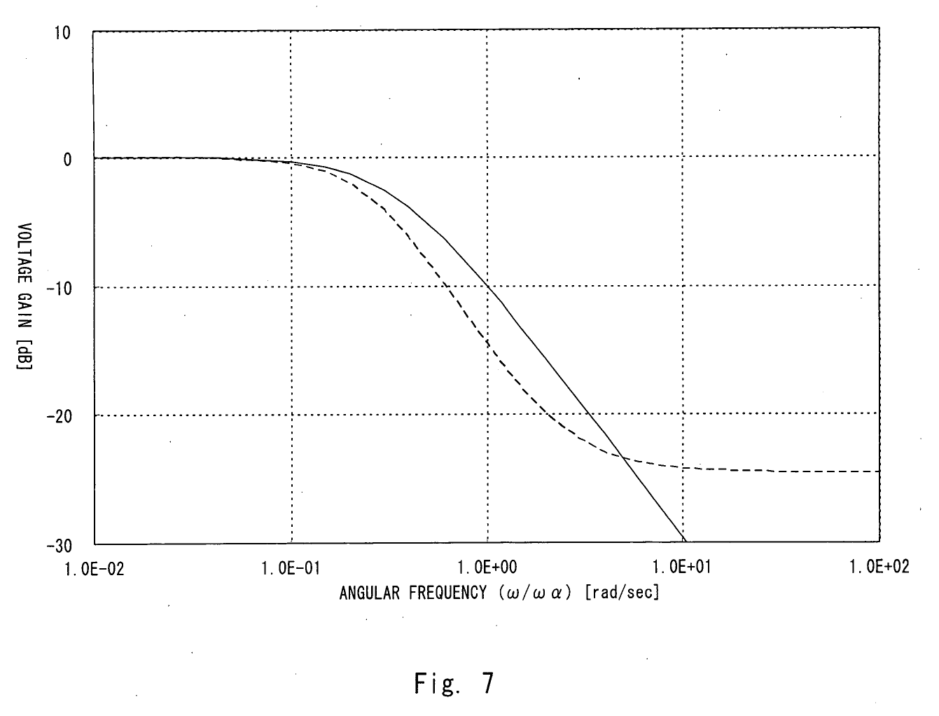

FIG. 7 shows a frequency characteristic obtained by numerical calculation in the case where the input number is two. Furthermore, FIG. 7 also shows a frequency characteristic of the analog multiplexer 9 shown in FIG. 11 obtained by numerical calculation. The following numerical values, which are calculated from a capacitance between connection points, a capacitance between connection points and housing, and a resistance between connection points, were used as the parameters in the numerical calculation.

(ω_{α}/ω_{β})=1.00

α=0.33

β=0.33

n=2

FIG. 7 is a graph of frequency characteristics in which an angular frequency (ω/ωα) based on ωα is used as the variable. In the graph, the solid line represents the frequency characteristic of the analog multiplexer 3 in accordance with this exemplary embodiment of the present invention, and the broken line represents the frequency characteristic of the analog multiplexer shown in FIG. 11. In FIG. 7, although the curvature of the frequency characteristic of the analog multiplexer 3 in accordance with this exemplary embodiment of the present invention is different from the curving shape of the frequency characteristic of the analog multiplexer 9 shown in FIG. 11, the voltage gain of this embodiment is higher than that of the analog multiplexer 9 shown in FIG. 11 in the passband at or lower than the cutoff frequency. From this fact, it can be understood that the frequency characteristic of the analog multiplexer 3 in accordance with this exemplary embodiment of the present invention is improved over that of the analog multiplexer 9 shown in FIG. 11.

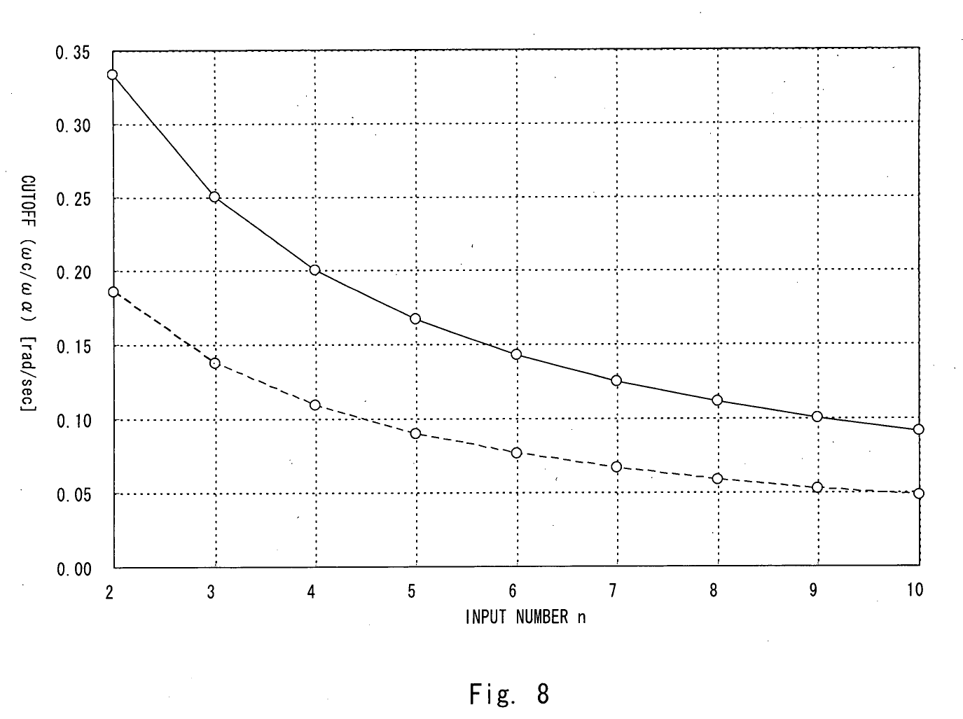

Next, FIG. 8 shows a change in the frequency characteristic in the analog multiplexer 3 in accordance with this exemplary embodiment of the present invention as the input number “n” is increased. Furthermore, FIG. 8 also shows a frequency characteristic of the analog multiplexer 9 shown in FIG. 11. FIG. 8, in which the number of inputs “n” is used as the variable, shows changes of the cutoff angular frequencies in the low-pass characteristics exhibited by the analog multiplexer 3 in accordance with this exemplary embodiment of the present invention and the analog multiplexer 9 shown in FIG. 11. In the graph, the angular frequency is expressed as an angular frequency (ω/ωα) based on ωα. The solid line represents the cutoff angular frequency of the analog multiplexer 3 in accordance with this exemplary embodiment of the present invention, and the broken line represents the cutoff angular frequency of the analog multiplexer 9 shown in FIG. 11. In the range from the point where the input number “n” is 2 to the point where the input number “n” is 10, the cutoff angular frequency of the analog multiplexer 3 in accordance with this exemplary embodiment of the present invention is about 1.8 times higher than that of the analog multiplexer shown in FIG. 11. From this fact, it can be understood that the frequency characteristic of the analog multiplexer 3 in accordance with this exemplary embodiment of the present invention is extended in terms of frequency band.

As has been described above, an On-resistance value and capacitance values associated with the electrodes in a switch using a relay in the analog multiplexer 3 in accordance with this embodiment of the present invention are not the same as those of the N-channel MOS transistor used in the analog multiplexer 1 of the firstly-described exemplary embodiment. However, the frequency characteristic can be still improved as in the case of the analog multiplexer 1 of the firstly-described exemplary embodiment.

Furthermore, a relay that opens and closes between the connection points can handle input signals having any voltage within the voltage range in which the relay can open and close. In general, it can handle a voltage larger than the voltage range that can be handled by a switch composed of an N-channel MOS transistor or a P-channel MOS transistor, and therefore it can handle an input voltage range that can be handled neither by the firstly-described exemplary embodiment nor the secondly-described exemplary embodiment of the present invention.

### Fourth Exemplary Embodiment

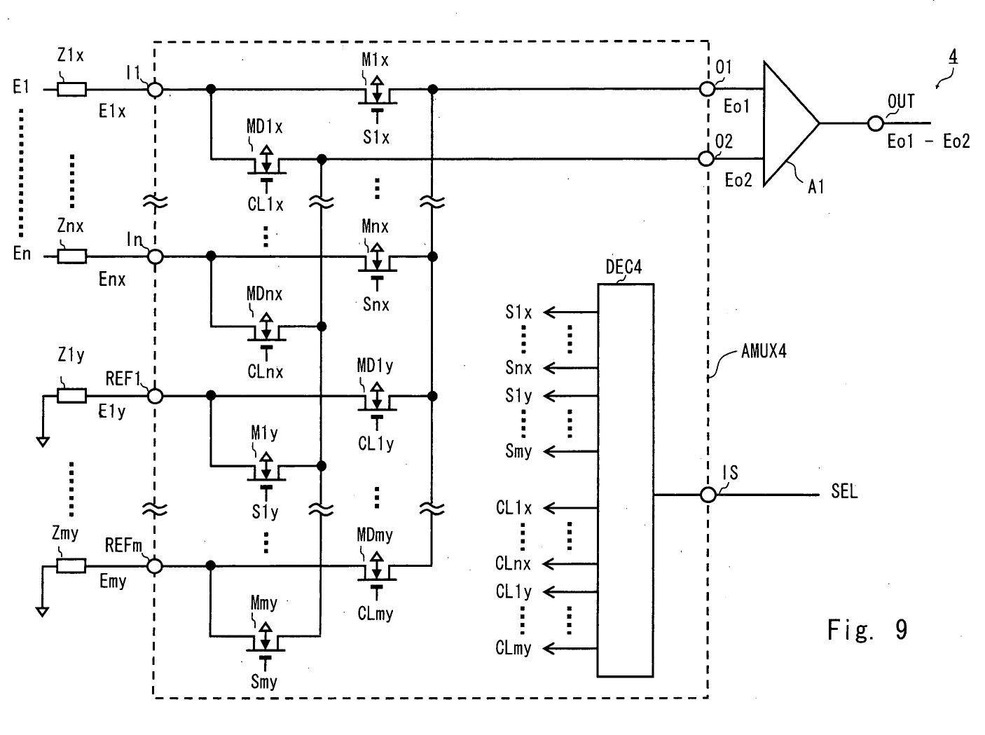

Next, an analog multiplexer in accordance with another exemplary embodiment of the present invention is explained hereinafter. FIG. 9 is a circuit diagram of an analog multiplexer 4 in accordance with another exemplary embodiment of the present invention. An analog multiplexer 4 in accordance with this exemplary embodiment of the present invention includes a switch portion AMUX4 that performs switching between input signals, and a buffer amplifier A1 that receives an output from the switch portion AMUX4, and amplifies and outputs the received output.

The switch portion AMUX4 includes 1st to nth (n=2, 3, 4, . . . ) input terminals II to In; 1st to mth (m=2, 3, 4, . . . ) reference voltage input terminals REF1 to REFm; a first output terminal O1; a second output terminal O2; 1xth to nxth switches M1x to Mnx (first switch portion) connected between the input terminals I1 to In and the first output terminal O1; 1yth to myth dummy switches MD1y to MDmy (third switch portion) connected between the 1st to mth reference voltage input terminals REF1 to REFm and the first output terminal O1; 1xth to nxth dummy switches MD1x to MDnx (second switch portion) connected between the 1st to nth input terminals I1 to In and the second output terminal O2; 1yth to myth switches M1y to Mmy (fourth switch portion) connected between the 1st to mth reference voltage input terminals REF1 to REFm and the second output terminal O2; and a decoder DEC4 that controls On/Off of the switches in accordance with a control signal SEL received from a control input terminal IS.

Each of 1st to nth input signals E1 to En is input to a corresponding one of the 1st to nth input terminals I1 to In of the switch portion AMUX4 through a corresponding one of 1xth to nxth impedances Z1x to Znx. Meanwhile, each of the 1st to mth reference voltage input terminals REF1 to REFm is connected to ground through a corresponding one of 1yth to myth impedances Z1y to Zmy.

The buffer amplifier A1 receives a first output signal Eo1 from the first output terminal O1 and a second output signal Eo2 from the second output terminal O2, generates a differential voltage Eo1-Eo2 between the output from the first output terminal O1 and the output from the second output terminal O2, amplifies the differential voltage to a level sufficient to drive a load connected to the buffer amplifier output terminal OUT, and outputs the amplified differential voltage.

The 1xth to-nxth switches M1x to Mnx, the 1yth to myth switches M1y to Mmy, the 1xth to nxth dummy switches MD1x to MDnx, and the 1yth to myth dummy switches MD1y to MDmy of the switch portion AMUX4 are N-channel MOS transistors. The drain electrodes of the 1xth to nxth switches M1x to Mnx and the drain electrodes of the respective 1xth to nxth dummy switches MD1x to MDnx are connected in common with the respective 1st to nth input terminals I1 to In. Furthermore, the drain electrodes of the 1yth to myth switches M1y to Mmy and the drain electrodes of the 1yth to myth dummy switches MD1y to MDmy are connected in common with the 1st to mth reference voltage input terminals REF1 to REFm. The source electrodes of the 1xth to nxth switches M1x to Mnx and the source electrodes of the 1yth to myth dummy switches MD1y to MDmy are all connected in common with the first output terminal O1. Furthermore, the source electrodes of the 1xth to nxth dummy switches MD1x to MDnx and the source electrodes of the 1yth to myth switches M1y to Mmy are all connected in common with the second output terminal O2. The gate electrodes of the 1xth to nxth switches M1x to Mnx, the 1yth to myth switches M1y to Mmy, the 1xth to nxth dummy switches MD1x to MDnx, and the 1yth to myth dummy switches MD1y to MDmy are connected to the 1xth to nxth decode outputs S1x to Snx, the 1yth to myth decode outputs S1y to Smy, the 1xth to nxth clamp outputs CL1x to CLnx, and the 1yth to myth clamp outputs CL1y to CLmy, respectively, of the decoder DEC4.

Next, an operation of the analog multiplexer 4 in accordance with this exemplary embodiment of the present invention shown in FIG. 9 in a case where the pth (1≦p≦n) input signal Ep is selected is explained hereinafter. The non-selected input signals, input terminals, switches, and the likes are expressed by using the sign “i” (1≦i≦n; i≠p). The 1xth to nxth decode outputs S1x to Snx of the decoder DEC4 are controlled such that the pxth switch Mkx is turned on and, at the same time, all of the ixth switches Mix are turned off. The pxth switch Mpx is located between the pth input terminal Ip and the first output terminal O1, and when turned on, it connects between the pth input terminal Ip and the first output terminal O1. The ixth switches Mix are connected to the non-selected ith (1≦i≦n; i≠p) input terminals.

At the same time, the outputs S1y to Smy of the decoder DEC4 are controlled such that the switch Mqx (1≦q≦m) is turned on and the hyth (1≦h≦m; h≠q) switches Mhy are turned off. Note that the switch Mqy is located between the qth reference voltage input terminal REFq to which the qyth impedance Zqy is connected and the second output terminal O2, and the qyth impedance Zqy has the same impedance as that of the pxth impedance Zpx connected to the pth input terminal Ip. By turning the switch Mqy on, the qth reference voltage input terminal REFq is connected to the second output terminal O2. Furthermore, the hyth switches Mhy are connected to the non-selected hth reference voltage input terminals REFh.

Furthermore, the 1xth to nxth clamp outputs CL1x to CLnx and 1yth to nyth clamp outputs CL1y to CLmy are controlled such that the 1xth to nxth dummy switches MD1x to MDnx and the 1yth to myth dummy switches MD1y to MDmy, respectively, are constantly in the Off-state. In this way, the 1xth to nxth dummy switches MD1x to MDnx and the 1yth to myth dummy switches MD1y to MDmy constitute a dummy switch circuit that is constantly fixed in the Off-state regardless of input switching.

In the analog multiplexer 4 in accordance with this exemplary embodiment of the present invention shown in FIG. 9, 1xth to nxth terminal voltages E1x to Enx are generated at the respective 1st to nth input terminals I1 to In to which the respective 1st to nth input signals E1 to En are supplied through the 1xth to nxth impedances Z1x to Znx. Furthermore, 1yth to myth reference voltage input terminal voltages E1y to Emy are generated at the respective 1st to mth reference voltage input terminals REF1 to REFm which are connected to ground through the 1yth to myth impedances Z1y to Zmy. Furthermore, each of the pxth switch Mpx and the qyth switch Mqy in the On-state can be replaced by the equivalent circuit shown in FIG. 13, and each of all the remaining switches in the Off-state can be replaced by the equivalent circuit shown in FIG. 14.

By replacing all of the transistor switches and the dummy transistor switches with the equivalent circuits according to their On/Off states based on the above-mentioned 1st to nth input terminal voltages E1x to Enx and the 1st to mth reference input terminal voltage E1y to Emy, an output signal Eo1 at the first output terminal O1 and an output signal Eo2 at the second output terminal O2 in a case where the pth input terminal Ip and the qth reference voltage input terminal REFq are selected can be expressed as the following equations (21) and (22) respectively.

$$\begin{matrix}{E}_{o 1} = ( {H}_{1 , n + m - 1} - {H}_{2 , n + m - 1} ) \cdot {E}_{px} + {H}_{2 , n + m - 1} \cdot ( {\sum }_{i = 1}^{n} {E}_{ix} + {\sum }_{i = 1}^{m} {E}_{iy} ) & ( 21 ) \\ {E}_{o 2} = ( {H}_{1 , n + m - 1} - {H}_{2 , n + m - 1} ) \cdot {E}_{qy} + {H}_{2 , n + m - 1} \cdot ( {\sum }_{i = 1}^{n} {E}_{ix} + {\sum }_{i = 1}^{m} {E}_{iy} ) & ( 22 )\end{matrix}$$

In the equations, the coefficients contained on the right sides of the equations (21) and (22) are obtained by replacing “n−1” with “n+m−1” in the equations (6) and (7), and expressed by the following equations (23) and (24) respectively.

$$\begin{matrix}{H}_{1 , n + m - 1} = \frac{1 + j \cdot ( ω / {ω}_{α} ) \cdot α}{1 + j \cdot ( ω / {ω}_{α} ) \cdot \{ 1 + ( n + m - 1 ) \cdot ( {ω}_{α} / {ω}_{β} ) \}} & ( 23 ) \\ {H}_{2 , n + m - 1} = \frac{j \cdot ( ω / {ω}_{α} ) \cdot ( {ω}_{α} / {ω}_{β} ) \cdot β}{1 + j \cdot ( ω / {ω}_{α} ) \cdot \{ 1 + ( n + m - 1 ) \cdot ( {ω}_{α} / {ω}_{β} ) \}} & ( 24 )\end{matrix}$$

A differential voltage Eo1-Eo2 between the output signal Eo1 at the first output terminal O1 and the output signal Eo2 at the second output terminal O2 that is to be generated by the buffer amplifier A1 is expressed as the following equation (25) from the equations (21) and (22).

Eₒ₁−Eₒ₂=(H_{1,n+m-1}−H_{2,n+m-1})·(Eₚₓ−E_{qy}) (25)

In the equation, the pth input terminal voltage Epx and the qth reference voltage input terminal voltage Eqy are expressed by the following equations (26) and (27) respectively.

Eₚₓ=H_{5,p}·Eₚ+H_{6,p}·Eₒ₁+H_{7,p}·Eₒ₂ (26)

E_{qy}=H_{8,q}·Eₒ₂+H_{9,q}·Eₒ₁ (27)

Coefficients in the equations (26) and (27) are expressed by the following equations (28), (29), (30), (31), and (32) respectively.

$$\begin{matrix}{H}_{5 , p} = \frac{R}{R + \{ 1 + j \cdot ω \cdot ( {C}_{α} + {C}_{β} ) \cdot R \} \cdot {Z}_{px}} & ( 28 ) \\ {H}_{6 , p} = \frac{( 1 + j \cdot ω \cdot α \cdot {C}_{α} \cdot R ) \cdot {Z}_{px}}{R + \{ 1 + j \cdot ω \cdot ( {C}_{α} + {C}_{α} ) \cdot R \} \cdot {Z}_{px}} & ( 29 ) \\ {H}_{7 , p} = \frac{j \cdot ω \cdot β \cdot {C}_{β} \cdot R \cdot {Z}_{px}}{R + \{ 1 + j \cdot ω \cdot ( {C}_{α} + {C}_{β} ) \cdot R \} \cdot {Z}_{px}} & ( 30 ) \\ {H}_{8 , q} = \frac{( 1 + j \cdot ω \cdot α \cdot {C}_{α} \cdot R ) \cdot {Z}_{qy}}{R + \{ 1 + j \cdot ω \cdot ( {C}_{α} + {C}_{α} ) \cdot R \} \cdot {Z}_{qy}} & ( 31 ) \\ {H}_{9 , q} = \frac{j \cdot ω \cdot β \cdot {C}_{β} \cdot R \cdot {Z}_{qy}}{R + \{ 1 + j \cdot ω \cdot ( {C}_{α} + {C}_{β} ) \cdot R \} \cdot {Z}_{qy}} & ( 32 )\end{matrix}$$

Note that since the impedances are determined so that the pth impedance Zpx connected to the pth input terminal Ip is equal to the qth impedance Zqy connected to the qth reference voltage input terminal REFp, the following equations (33) and (34) are satisfied.

H_{6,p}=H_{9,q} (33)

H_{7,p}=H_{8,q} (34)

By rewriting the equation (25) by using the equations (33) and (34), the following equation (35) is obtained. The coefficient multiplied to the pth input signal Ep indicates a frequency characteristic from the input to the buffer amplifier output terminal OUT in a case where the input signal is supplied through the pxth impedance Zpx. Furthermore, since the right side of the equation (35) does not contain input signals Ei supplied to the non-selected ith input terminals Ii (i≠p) through the ixth impedances Zix, the output from the buffer amplifier A1 does not contain any crosstalk component.

$${E}_{o 1} - {E}_{o 2} = \frac{( {H}_{1 , n + m - 1} - {H}_{2 , n + m - 1} ) \cdot {H}_{5 , p}}{1 - ( {H}_{1 , n + m - 1} - {H}_{2 , n + m - 1} ) \cdot ( {H}_{6 , p} - {H}_{7 , p} )} \cdot {E}_{p} \qquad ( 35 )$$

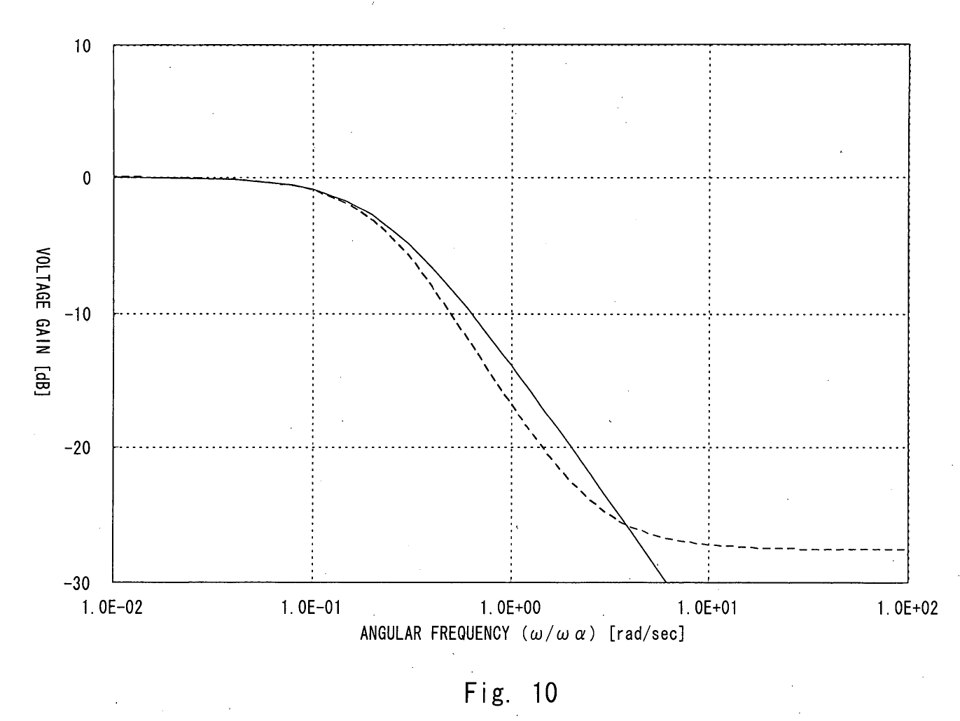

Next, FIG. 10 shows a frequency characteristic from the input to the output terminal OUT obtained by numerical calculation in the case where the input number is three. Furthermore, FIG. 10 also shows a frequency characteristic of the analog multiplexer 9 shown in FIG. 11 obtained by numerical calculation. Values extracted from electrical characteristics between terminals of an N-channel MOS transistor were used as the parameters in the numerical calculation. Furthermore, the calculation was performed with an assumption that the reference voltage input terminal number “m” is two, and the impedances connected to the input terminals and the reference voltage input terminals are pure resistances and their values are 0.3 times as large as the On-resistance of switches.

(ω_{α}/ω_{β})=0.54

α=0.49

β=0.08

Zₖ/R=0.3

n=3

m=2

FIG. 10 is a graph of frequency characteristics in which an angular frequency (ω/ωα) based on ωα is used as the variable. In the graph, the solid line represents the frequency characteristic of the analog multiplexer 4 in accordance with this exemplary embodiment of the present invention, and the broken line represents the frequency characteristic of the analog multiplexer 9 shown in FIG. 11. In FIG. 10, although the curvature of the frequency characteristic of the analog multiplexer 4 in accordance with this exemplary embodiment of the present invention is different from the curving shape of the frequency characteristic of the analog multiplexer shown in FIG. 11, the voltage gain of this embodiment is higher than that of the analog multiplexer 9 shown in FIG. 11 in the passband at or lower than the cutoff frequency. From this fact, it can be understood that the frequency characteristic of the analog multiplexer 4 in accordance with this exemplary embodiment of the present invention is improved over that of the analog multiplexer 9 shown in FIG. 11.

In general, the output impedance of a signal source connected to an input of an analog multiplexer is not “0”. However, the analog multiplexer 4 in accordance with this exemplary embodiment of the present invention can completely eliminate the crosstalk component by connecting the same impedance as the impedance of the signal source between the reference voltage input terminal and the ground.

In a case where the inputs of the analog multiplexer 4 are composed of a plurality of signal sources having different output impedances, the same number of reference voltage input terminals as the number of types of those output impedances are provided and the impedance that is connected to the reference voltage input terminal is switched in accordance with the output impedance of the selected signal source, so that the crosstalk can be completely eliminated. Furthermore, even in the case where only one signal source is connected, if its output impedance can be switched between several values, the number of the reference voltage input terminals is increased to the number of those impedance values and the impedance that is connected to the reference voltage input terminal is switched in accordance with the output impedance of the signal source, so that the crosstalk can be completely eliminated. Furthermore, even in the case where only one signal source is connected, if the output impedance of its output can be changed in a continuous manner, the impedance that is connected to the corresponding reference voltage input terminal may be replaced with variable impedance.

Furthermore, in this exemplary embodiment of the present invention, the impedance may contain not only the pure resistance component but also a capacitive or inductive reactance component.

### Other Exemplary Embodiments

Although each of the above-described exemplary embodiments has been explained with a specific circuit configuration, the present invention is not limited to the above-described circuit configurations. Any configuration other than the above-described exemplary embodiments can be also adopted, provided that the switch circuit potion, which is assumed to have the function realized by the first to fourth switch portions 11 to 14 shown in FIG. 1, has a configuration that can realize the following functions.

For example, the switch circuit portion may be composed of a first switch circuit portion and a second switch circuit portion. The first switch circuit portion includes switches each of which is connected between a respective one of a plurality of input terminals and a first output terminal. The first switch circuit portion connects between the input terminals and the first output terminal and between a reference voltage input terminal and the first output terminal. The first switch circuit portion generates a first output signal containing an input signal selected by the switches based on a control signal and a crosstalk component caused between the plurality of input terminals and the first output terminal and between the reference voltage input terminal and the first output terminal, and outputs the generated first output signal to the first output terminal. The second switch circuit portion connects between the plurality of input terminals and the second output terminal and between the reference voltage input terminal and the second output terminal. The second switch circuit portion generates a second output signal containing the same component as the crosstalk component contained in the first output signal by using a crosstalk component caused between the plurality of input terminal and the second output terminal and between the reference voltage input terminal and the second output terminal, and outputs the generated second output signal to the second output terminal. Note that the number of the reference voltage terminal(s) may be one or more than one.

The only requirements are that the crosstalk components become the same between the first switch circuit portion and the second switch circuit portion, and one switch is located between each of the input terminals and the first output terminal in the first switch circuit portion. If these requirements are satisfied, the first switch circuit portion and the second switch circuit portion may be realized by any configurations other than the above-described exemplary embodiments. In the firstly-described exemplary embodiment, an aspect where the first switch circuit portion is realized by the first switch portion 11 and the third switch portion 13, and the second switch circuit portion is realized by the second switch portion 12 and the fourth switch portion 14 as shown in FIG. 1.

Note that not only an N-channel MOS transistor, but also a P-channel MOS transistor, or even a parallel circuit of an N-channel MOS transistor and a P-channel MOS transistor can be used as a switch for use in an analog multiplexer in accordance with an exemplary embodiment of the present invention. Furthermore, a relay that mechanically opens and closes between the connection points may be also used as a switch.

As has been described so far, in an exemplary embodiment in accordance with the present invention, the number of switch that is located between each of the plurality of input terminals and the output terminal and used to switch the input is one. Furthermore, a dummy circuit composed of switches that are connected between the respective input terminals and the second output terminal, between the first output terminal and the reference voltage input terminal, and between the second output terminal and the reference voltage input terminal, respectively, is provided to output a differential voltage between the first output terminal and the second output terminal, so that the crosstalk component caused at the output is eliminated. Therefore, the frequency characteristic between the input and the output can be extended in terms of frequency band.

Further, the above-described exemplary embodiments can be combined as desirable by one of ordinary skill in the art.

Note that the present invention is not limited to the above-described exemplary embodiments. Those skilled in the art can easily make modifications, additions, and conversions to each component of the above-described exemplary embodiments without departing from the scope of the present invention.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. An analog multiplexer comprising:
a plurality of input terminals;
at least one reference voltage input terminal;
a first output terminal;
a second output terminal;
a first switch portion comprising a plurality of switches, the plurality of switches being connected between the respective input terminals and the first output terminal and configured to establish a conductive state between one of the plurality of input terminals and the first output terminal based on a control signal;
a second switch portion comprising a plurality of switches, the plurality of switches being connected between the respective input terminals and the second output terminal and set to a non-conductive state;
a third switch potion comprising at least one switch, the at least one switch being connected between the reference voltage input terminal and the first output terminal and set to a non-conductive state;
a fourth switch potion comprising at least one switch, the at least one switch being connected between the reference voltage input terminal and the second output terminal and set to a conductive state; and
an output portion that outputs a differential potential between the first output terminal and a second output terminal.

2. The analog multiplexer according to claim 1, wherein:
the first output terminal outputs a first output signal containing one selected input signal and a crosstalk component from the plurality of input terminals to the first output terminal; and
the second output terminal outputs a second output signal containing the same component as the crosstalk component.

3. The analog multiplexer according to claim 1, wherein, if the number of the plurality of input terminals is “n” (n≧2):
the first switch portion comprises n switches each of which is connected between a respective one of the input terminals and the first output terminal; and
the second switch portion comprises n switches each of which is connected between a respective one of the input terminals and the second output terminal.

4. The analog multiplexer according to claim 2, wherein, if the number of the plurality of input terminals is “n” (n≧2):
the first switch portion comprises n switches each of which is connected between a respective one of the input terminals and the first output terminal; and
the second switch portion comprises n switches each of which is connected between a respective one of the input terminals and the second output terminal.

5. The analog multiplexer according to claim 1, wherein switches included in the first switch portion, the second switch portion, the third switch portion, and the fourth switch portion are formed of N-channel MOS transistors.

6. The analog multiplexer according to claim 2, wherein switches included in the first switch portion, the second switch portion, the third switch portion, and the fourth switch portion are formed of N-channel MOS transistors.

7. The analog multiplexer according to claim 3, wherein switches included in the first switch portion, the second switch portion, the third switch portion, and the fourth switch portion are formed of N-channel MOS transistors.

8. The analog multiplexer according to claim 4, wherein switches included in the first switch portion, the second switch portion, the third switch portion, and the fourth switch portion are formed of N-channel MOS transistors.

9. The analog multiplexer according to claim 1, wherein switches included in the first switch portion, the second switch portion, the third switch portion, and the fourth switch portion are formed of P-channel MOS transistors.

10. The analog multiplexer according to claim 2, wherein switches included in the first switch portion, the second switch portion, the third switch portion, and the fourth switch portion are formed of P-channel MOS transistors.

11. The analog multiplexer according to claim 3, wherein switches included in the first switch portion, the second switch portion, the third switch portion, and the fourth switch portion are formed of P-channel MOS transistors.

12. The analog multiplexer according to claim 4, wherein switches included in the first switch portion, the second switch portion, the third switch portion, and the fourth switch portion are formed of P-channel MOS transistors.

13. The analog multiplexer according to claim 1, wherein each switch included in the first switch portion, the second switch portion, the third switch portion, and the fourth switch portion is formed by connecting an N-channel MOS transistor and an N-channel MOS transistor in parallel.

14. The analog multiplexer according to claim 2, wherein each switch included in the first switch portion, the second switch portion, the third switch portion, and the fourth switch portion is formed by connecting an N-channel MOS transistor and an N-channel MOS transistor in parallel.

15. The analog multiplexer according to claim 3, wherein each switch included in the first switch portion, the second switch portion, the third switch portion, and the fourth switch portion is formed by connecting an N-channel MOS transistor and an N-channel MOS transistor in parallel.

16. The analog multiplexer according to claim 1, wherein switches included in the first switch portion, the second switch portion, the third switch portion, and the fourth switch portion are formed of relays.

17. The analog multiplexer according to claim 2, wherein switches included in the first switch portion, the second switch portion, the third switch portion, and the fourth switch portion are formed of relays.

18. The analog multiplexer according to claim 1, further comprising m (m≧1) types of impedances, wherein:
each of the input terminals receives an input signal through one of the m types of impedances;
the at least one reference voltage input terminal comprises m reference voltage input terminals, each of the m reference voltage input terminals being connected to ground through a different type of-impedance;
the third switch portion comprises m switches connected between the m reference voltage input terminals and the first output terminal; and
the fourth switch portion comprises m switches connected between the m reference voltage input terminals and the second output terminal.

19. An analog multiplexer comprising:
a plurality of input terminals;
at least one reference voltage input terminal;
a first output terminal;
a second output terminal;
a first switch circuit potion comprising switches each of which is connected between a respective one of the plurality of input terminals and the first output terminal, the first switch circuit potion being configured to generate a first output signal containing an input signal selected by the switches based on a control signal and a crosstalk component caused between the plurality of input terminals and the first output terminal and between the at least one reference voltage input terminal and the first output terminal, and output the generated first output signal to the first output terminal;
a second switch circuit portion that generates a second output signal containing the same component as the crosstalk component contained in the first output signal by using a crosstalk component caused between the plurality of input terminal and the second output terminal and between the at least one reference voltage input terminal and the second output terminal, and outputs the generated second output signal to the second output terminal; and
an output portion that outputs a differential potential between the first output terminal and the second output terminal.

20. A method of generating a select signal of an analog multiplexer, the analog multiplexer comprising a plurality of input terminals, at least one reference voltage input terminal, a first output terminal, and a second output terminal, the method comprising:
selecting an input signal by switches based on a control signal, each of the switches being connected between a respective one of the plurality of input terminals and the first output terminal;
generating a first output signal containing the selected input signal and a crosstalk component caused between the plurality of input terminals and the first output terminal and between the at least one reference voltage input terminal and the first output terminal, and outputting the generated first output signal to the first output terminal;
generating a second output signal containing the same component as the crosstalk component contained in the first output signal by using a crosstalk component caused between the plurality of input terminals and the second output terminal and between the at least one reference voltage input terminal and the second output terminal, and outputting the generated second output signal to the second output terminal; and
outputting a differential potential between the first output terminal and the second output terminal.
